(19) United States
(12) Patent Application Publication
(10) Pub. No.: US 2025/0006599 A1
(43) Pub. Date: Jan. 2, 2025

(54) Alternating Lead Configuration for Semiconductor Package

(71) Applicant: Texas Instruments Incorporated, Dallas, TX (US)

(72) Inventors: Dolores P. Milo, Baguio City (PH); Gloria B. Manaois, Baguio City (PH); Michael F. Milo, Baguio City (PH)

(21) Appl. No.: 18/345,566

(22) Filed: Jun. 30, 2023

(51) Int. Cl. H01L 23/495; H01L 23/00; H01L 23/31

(52) U.S. Cl. CPC H01L 23/49548; H01L 23/3107; H01L 24/48; H01L 2224/48247; H01L 2924/181

(57) ABSTRACT

A semiconductor package comprises a leadframe segment having a plurality of external leads. The external leads each have a first cross-section shape or a second cross-section shape. A semiconductor die is electrically coupled to the leadframe segment. An encapsulant covers the semiconductor die and a portion of the leadframe segment. External leads are exposed from the encapsulant on at least one side of the semiconductor package. The exposed external leads are arranged so that adjacent leads alternate between the first cross-section shape and the second cross-section shape. The second cross-section shape is a mirror image of the first cross-section shape.

### BACKGROUND

Semiconductor packages often have contact leads extending from package molding. During manufacture and testing, these semiconductor packages may become entangled with each other, such as when the external contact leads on multiple units become interleaved. During high-volume production of such semiconductor packages, the entangled packages can jam or stick assembly and test equipment, which may result in manufacturing delays and improper testing of the packages.

### SUMMARY

In one arrangement, a semiconductor package comprises a leadframe segment having a plurality of external leads. The external leads each have a first cross-section shape or a second cross-section shape. A semiconductor die is electrically coupled to the leadframe segment. An encapsulant covers the semiconductor die and a portion of the leadframe segment. External leads are exposed from the encapsulant on at least one side of the semiconductor package. The exposed external leads are arranged so that adjacent leads alternate between the first cross-section shape and the second cross-section shape. The second cross-section shape is a mirror image of the first cross-section shape. At least a portion of each external lead is covered by the encapsulant. The covered portions of the external leads have either the first cross-section shape or the second cross-section shape, which allows the encapsulant to lock onto the leadframe segment.

In one configuration, the first cross-section shape is an upright T-shape and the second cross-section shape is an inverted T-shape. In another configuration, the first cross-section shape is a forward-facing Z-shape and the second cross-section shape is a backward-facing Z-shape.

The external leads have a lead width, and individual external leads are spaced apart by the lead width. The lead width may be the width of a horizontal bar on a lead with a T-shape cross-section. The lead width may be the width from an outside edge of an upper horizontal bar to an outside edge of a lower horizontal bar on a lead with a Z-shape cross-section.

The first cross-section shape and the second cross-section shape are created by etching material from the external leads. Alternatively, the first cross-section shape and the second cross-section shape are created by stamping a leadframe sheet to form the external leads.

In another arrangement, semiconductor device, comprises an integrated circuit (IC) die mounted on a leadframe. A mold compound covers the IC die and at least a portion of the leadframe. A first group of leadframe leads are exposed from a first side of the mold compound. Each of the first group of lead portions have a cross-section shape. The cross-section shape of adjacent leads alternate between a first shape or a second shape. The leads each have the same lead width, and adjacent leads are spaced apart by the lead width. A second group of leadframe leads are exposed from a second side of the mold compound. Each of the second group of lead portions have a cross-section shape. The cross-section shape of adjacent leads on the second side also alternate between the first shape or the second shape.

The cross-section shape is defined by notches in the leads. The notches are configured to permit unrestrained movement when a second group of leads on another semiconductor device are interleaved between the first group of leads.

The first shape is an upright T-shape or a forward-facing Z-shape and the second cross-section shape is an inverted T-shape or a backward-facing Z-shape.

A leadframe segment for a semiconductor package comprises a first set of external leads each having a first cross-section shape, and a second set of external leads each having a second cross-section shape. The second set of external leads are interleaved between the first set of external leads. Each of the external leads in the first set and the second set have a same lead width. Adjacent external leads are spaced apart by the lead width.

In one arrangement, the first cross-section shape is an upright T-shape formed by etching material from opposite bottom corners of the first set of external leads. The second cross-section shape is an inverted T-shape formed by etching material from opposite top corners of the second set of external leads.

In another arrangement, the first cross-section shape is a forward-facing Z-shape formed by etching material from a first pair of diagonally opposed top and bottom corners on the first set of external leads. The second cross-section shape is a backward-facing Z-shape formed by etching material from a second pair of diagonally opposed top and bottom corners on the second set of external leads.

The first cross-section shape and the second cross-section shape are configured to permit unrestrained movement when external leads of two semiconductor packages are interleaved.

### BRIEF DESCRIPTION OF THE DRAWINGS

Having thus described the invention in general terms, reference will now be made to the accompanying drawings, wherein:

FIG. 1 illustrates an example semiconductor package having two rows of external leads on opposite sides along the bottom of the package.

FIG. 2 illustrates external leads on a first semiconductor package becoming interleaved and entangled with external leads on a second semiconductor package.

FIG. 3 is a side view of a semiconductor package having external leads with generally T-shaped cross-sections organized in an alternating upright and inverted order.

FIG. 4 is a side view of a semiconductor package having external leads with generally T-shaped cross-sections organized in a different upright and inverted order compared to FIG. 3.

FIG. 5 shows details of an external lead having a generally T-shaped cross-section.

FIGS. 6A and 6B are different views illustrating a first semiconductor package having a first set of external leads interleaved with a second set of external leads on a second semiconductor package wherein the leads have T-shaped cross-sections.

FIGS. 7A and 7B are different views illustrating a first semiconductor package having a first set of external leads interleaved with a second set of external leads on a second semiconductor package with the external leads organized in a different order compared to FIGS. 6A and 6B.

FIG. 8 illustrates a portion of a semiconductor package having several leadframe segments.

FIG. 9 is a side view of a semiconductor package having a number of external leads with a generally Z-shaped cross-section.

FIG. 10 shows details of an external lead having a generally Z-shaped cross-section.

FIGS. 11A and 11B are different views illustrating a first semiconductor package having a first set of external leads interleaved with a second set of external leads on a second semiconductor package where the leads have Z-shaped cross-sections.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

Corresponding numerals and symbols in the different figures generally refer to corresponding parts, unless otherwise indicated. The figures are not necessarily drawn to scale. In the drawings, like reference numerals refer to like elements throughout, and the various features are not necessarily drawn to scale. In the following discussion and in the claims, the terms “including,” “includes,” “having,” “has,” “with,” or variants thereof are intended to be inclusive in a manner similar to the term “comprising,” and thus should be interpreted to mean “including, but not limited to . . . ” Also, the terms “coupled,” “couple,” and/or or “couples” is/are intended to include indirect or direct electrical or mechanical connection or combinations thereof. For example, if a first device couples to or is electrically coupled with a second device that connection may be through a direct electrical connection, or through an indirect electrical connection via one or more intervening devices and/or connections. Elements that are electrically connected with intervening wires or other conductors are considered to be coupled. Terms such as “top,” “bottom,” “front,” “back,” “over,” “above,” “under,” “below,” and such, may be used in this disclosure. These terms should not be construed as limiting the position or orientation of a structure or element but should be used to provide spatial relationship between structures or elements.

The term “semiconductor die” is used herein. A semiconductor die refers to a thin slice of material, such as crystalline silicon, that is used to fabricate integrated circuits. A large number of integrated circuits may be created on an active surface of the semiconductor die. Discrete semiconductor devices can be integrated circuits with hundreds or thousands of transistors coupled to form a functional circuit, for example a microprocessor or memory device. The semiconductor device may also be referred to herein as a semiconductor wafer or an integrated circuit (IC) die.

The term “semiconductor package” is used herein. A semiconductor package has at least one semiconductor die electrically coupled to terminals and has a package body that protects and covers the semiconductor die. In some arrangements, multiple semiconductor dies can be packaged together. For example, a power metal oxide semiconductor (MOS) field effect transistor (FET) semiconductor device and a second semiconductor device (such as a gate driver die, or a controller die) can be packaged together to form a single packaged electronic device. Additional components such as passive components, such as capacitors, resistors, and inductors or coils, can be included in the packaged electronic device. The semiconductor die is mounted with a package substrate that provides conductive leads. A portion of the conductive leads form the terminals for the packaged device. In wire bonded integrated circuit packages, bond wires couple conductive leads of a package substrate to bond pads on the semiconductor die. The semiconductor die can be mounted to the package substrate with a device side surface facing away from the substrate and a backside surface facing and mounted to a die pad of the package substrate. The semiconductor package can have a package body formed by a thermoset epoxy resin mold compound in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions form the terminals for the semiconductor package. The semiconductor package may also be referred to as a “integrated circuit package,” a “microelectronic device package,” or a “semiconductor device package.”

The term “external lead” is used herein. In packaged integrated circuits, external leads provide an electrical connection from contacts or pads on the exterior of a semiconductor package to an internal leadframe that is coupled to a semiconductor die within the package. The external lead is a portion of the leadframe that is exposed outside of a mold compound or other protective encapsulant for the semiconductor package. The leadframe and the external leads may be etched, stamped, or cut to have a desired cross-section shape.

The terms “T-shaped” and “Z-shaped” are used herein to describe the cross-section shape of an external lead. As used herein, T-shaped refers to a cross-section shape that generally looks like a capital “T” in the English alphabet (i.e., a horizontal bar element having a centered vertical stem descending from the bar). A T-shaped cross-section may be oriented upright (i.e., bar on top) or inverted (i.e., bar on bottom). As used herein, Z-shaped refers to a cross-section shape that generally looks like a capital “Z” in the English alphabet (i.e., upper and lower horizontal bar elements having a stem attached to opposite ends of the horizontal bars). A Z-shaped cross-section may be oriented as forward facing (i.e., the stem connects the right side of the upper bar to the left side of the lower bar) or backward facing (i.e., the stem connects the left side of the upper bar to the right side of the lower bar).

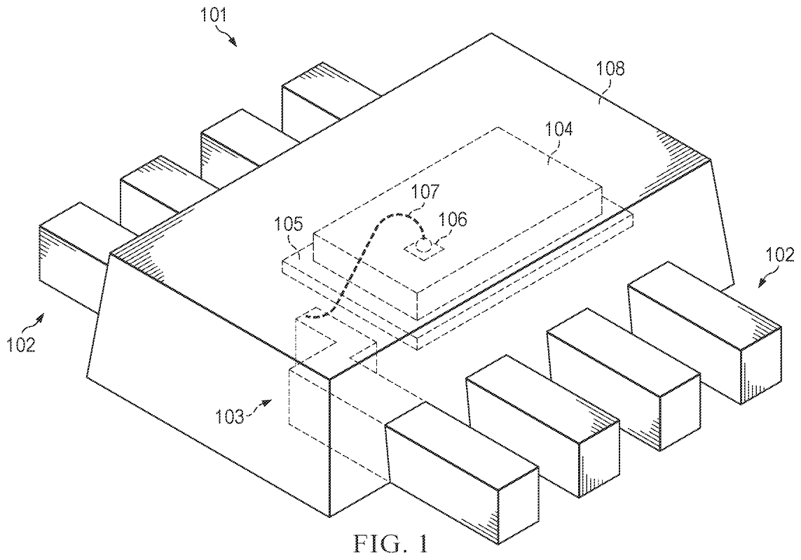

FIG. 1 illustrates an example Small Outline Transistor (SOT) package 101, such as a Surface Mount Transistor (SMT) commonly used for automotive, industrial, and consumer electronics applications. SOT package 101 has two rows of external leads 102 along the bottom of the package on opposite side. External leads 102 are part of a leadframe 103 that couples an internal semiconductor die 104 to the external leads 102. Leadframe 103 may include a die attach pad 105 for mounting the semiconductor die 104. Contacts 106 on semiconductor die 104 are connected to leadframe 103 and external leads 102 via bond wires 107. FIG. 1 shows just a portion of the leadframe 103, contacts 106, and other components to simplify the drawing. The semiconductor die 104 and leadframe 103 are encased in a protective mold compound 108 that exposes the external leads 102.

Multiple SOT packages 101 may be manufactured at the same time using a single leadframe sheet. After the semiconductor dies are mounted on and attached to leadframe 103 and mold compound 108 applied, individual SOT packages are severed (“singulated” or “diced”) from each other with a cutting tool, such as a saw or laser, into separate units. Each SOT package includes a singulated leadframe, at least one semiconductor die, electrical connections between the die and leadframe (e.g., wire bonds), mold compound that covers these structures, and external leads extending from the mold compound.

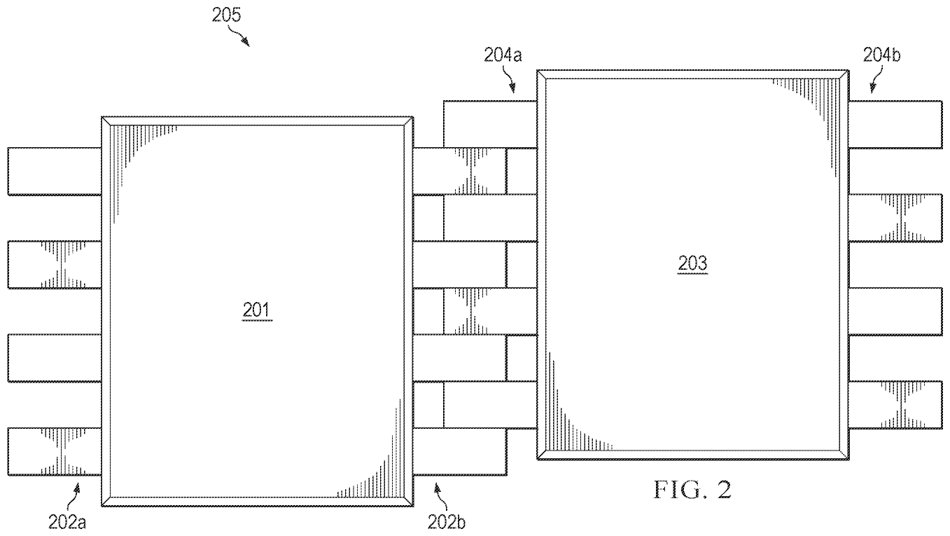

FIG. 2 illustrates a problem that can arise during processing of singulated semiconductor package units using existing lead configurations, such as leads having a rectangular cross-section. First semiconductor package 201 has external leads 202a, 202b on opposite sides. Second semiconductor package 203 has external leads 204a, 204b on opposite sides. Due to the packages' size and the external lead configuration, external leads 202b on package 201 become interleaved and entangled with external leads 204a on package 203. This results in packages 201 and 203 linking together to form a larger single unit 205. Additional semiconductor packages (not shown) may become further entangled with the other exposed leads 202a, 204b on packages 201 or 203 which will create an even larger unit having multiple linked semiconductor packages. The individual semiconductor packages will be more susceptible to entanglement if the width of the external leads 202a,b and 204a,b is the same as the spacing of these external leads.

After completing the manufacturing process, packages 201 and 203 may be routed for testing. The combined unit 205 has to move through testing processes that are sized and configured for the individual semiconductor packages 201, 203. Automated Test Equipment (ATE) or other computer-controlled systems may be configured to perform tests on the packages to ensure that they meet design specifications, standards, and customer requirements using an automated testing process. The ATE assembly reduces operator intervention and allows for rapid testing. An ATE assembly may include a bowl feeder that is configured to feed parts to a test handler at high speed for testing. Semiconductor packages that are deformed or have a nonstandard configuration can jam the bowl feeder machinery and other testing components. The entangled unit 205 would cause such jams since it is approximately twice the size of the expected individual semiconductor packages 201, 203.

In one arrangement, the configuration of the external leads may be designed to minimize or prevent entanglement between adjacent semiconductor packages. For example, alternating etched areas on each of the parallel leads can prevent the external leads from getting stuck between leads on neighboring packages. This configuration would allow the semiconductor packages to maintain an external lead spacing that is the same as the external lead width.

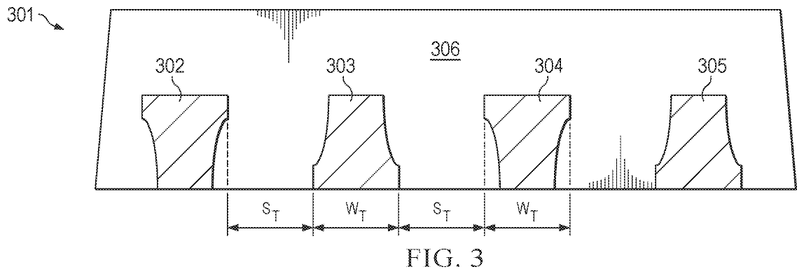

FIG. 3 is a side view of a semiconductor package 301 having a number of external leads 302-305 that are extending from mold compound 306. The external leads 302-305 have a generally T-shaped cross-section wherein one side (i.e., either the top or bottom) is wider than an opposite side. The shape of the external leads 302-305 alternate so that the orientation of each lead is opposite to its neighboring leads. For example, leads 302 and 304 have an upright T-shape cross-section while leads 303 and 305 have an inverted T-shape cross-section.

In one arrangement, external leads 302-305 have a maximum width W_{T} and are spaced a distance S_{T} apart. By alternating the cross-section configuration of each lead, the external leads 302-305 can be spaced apart by the width of the lead (i.e., so that S_{T}=W_{T}).

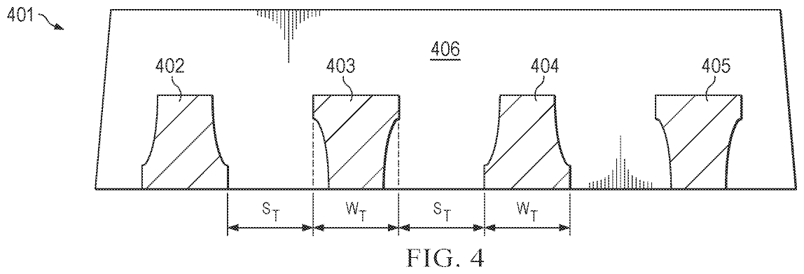

FIG. 4 is a side view of a semiconductor package 401 having a number of external leads 402-405 that are extending from mold compound 406 wherein the configuration of the external leads is different from the example shown in FIG. 3. The external leads 402-405 have a generally T-shaped cross-section. The shape of the external leads 402-405 alternate so that the orientation of each lead is opposite to its neighboring leads. As shown in FIG. 4, leads 402 and 404 have an inverted T-shape cross-section while leads 403 and 405 have an upright T-shape cross-section. Also, like semiconductor package 301, in semiconductor package 401 the external leads 402-405 have a maximum width W_{T} and are spaced a distance S_{T} apart so that the external leads 402-405 can be spaced apart by the width of the leads.

Although four external leads are shown on the sides of semiconductor packages 301 and 401, it will be understood that the use of alternating lead cross-section shapes may be applied to semiconductor packages having any number of external leads. Furthermore, it will be understood that the use of alternating lead cross-section shapes may be applied to semiconductor packages having different numbers of external leads on two or more sides of the semiconductor packages (e.g., three external leads on one side and four external leads on an opposite side).

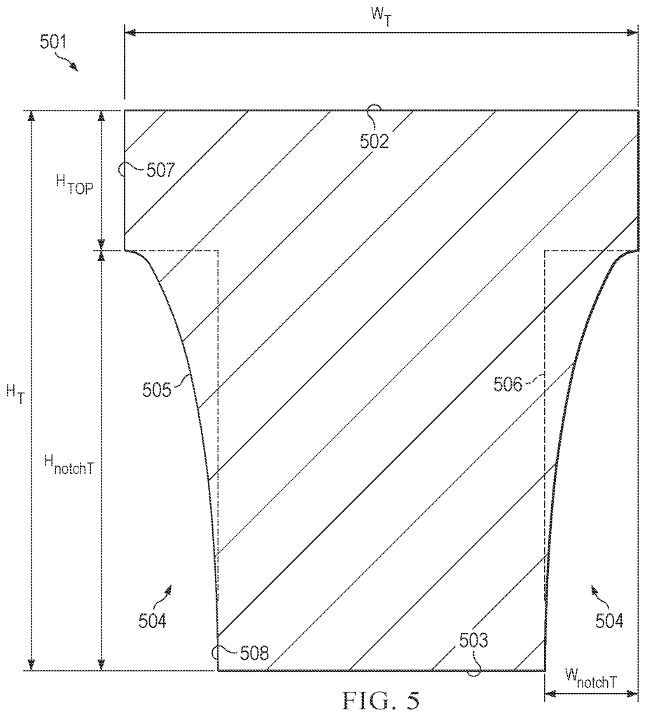

FIG. 5 is a cross-section view of an external lead 501 according to one configuration. Lead 501 has a generally T-shaped cross-section with a wide end 502 and a narrow end 503 opposite the wide end. Lead 501 has a maximum width W_{T} and a height H_{T}. The external lead 501 is a portion of a leadframe that has been singulated from a leadframe strip during manufacturing of a semiconductor package. The lead 501 is a metal material, such as copper, that has been cut, stamped, or etched to create the T-shaped cross-section of lead 501.

Material has been removed to create notched regions 504 along the sides of the lead 501. Depending upon the amount of material removed and the process used to remove the material (e.g., etching, stamping, or cutting), the notched region 504 may have a sloped surface 505. In another arrangement, removal of the notch material may create a notch region 504 having flatter or squared off surface as shown by dashed line 506. The notch regions 504 have a width W_{notchT} and a height H_{notchT}. In one arrangement, the size of W_{notchT} is approximately 15% of W_{T}, and the size of H_{notchT} is approximately 75% of H_{T}.

There are two notch regions 504 on lead 501. In some arrangements, the width W_{notchT} and the height H_{notchT} of both notches 504 are the same. In other arrangements, the notch regions 504 on opposite sides of lead 501 may have different heights and/or widths so that on one side the notch region 504 is wider and/or higher than the notch region 504 on the other side of the lead. While lead 501 is shown in FIG. 5 in an upright T-shape configuration, it will be understood that an inverted T-shape configuration may be created by removing material from the top of lead 501 to create notched regions 504. The height of either notch region should exceed the height H_{TOP} of the top portion 507, which will allow adjacent upright and inverted T-shaped leads 501 to overlap.

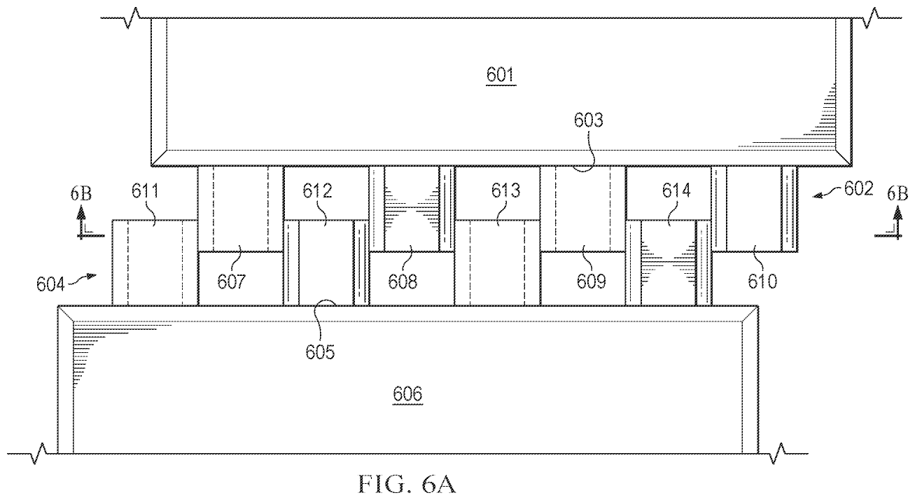

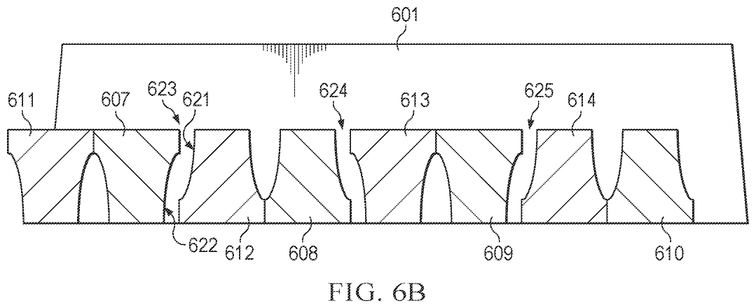

FIG. 6A shows a top-down view of a first semiconductor package 601 having a first set of external leads 602 extending from side 603. External leads 602 are interleaved with a second set of external leads 604 that extend from side 605 of a second semiconductor package 606. The first set of external leads 602 includes upright T-shaped leads 607 and 609 that are interspaced with inverted T-shaped leads 608 and 610. The second set of external leads 604 includes upright T-shaped leads 611 and 613 that are interspaced with inverted T-shaped leads 612 and 614.

FIG. 6B is a cross-section view through the interleaved sets of external leads 602, 604. The orientation of the external leads on each semiconductor package 601, 606 results in pairs of interleaved leads that have the same orientation (i.e., pairs of upright T-shapes or inverted T-shapes). For example, lead 607 from package 601 and adjacent lead 611 from package 606 both have an upright T-shaped configuration. On the other hand, lead 608 from package 601 and adjacent lead 612 from package 606 both have an inverted T-shaped configuration. Because these pairs have the same orientation, external leads 607 and 608 of package 601 bump up against external leads 611 and 612, respectively, on package 606. Therefore, package 601 (and leads 607, 608) cannot move any further leftward in the figure.

The notched region 621 on lead 612 and the notched region 622 on lead 607 create a space 623 between those external leads 607, 612. This space 623 allows external lead 607 to move further rightward in the figure toward lead 612 and away from lead 611. Accordingly, the movement permitted by space 623 prevents lead 607 (on package 601) from being locked between leads 611 and 612 (on package 606). Similarly, notched regions on the other leads create spaces 624 and 625. Spaces 624 and 625 prevent leads 608 and 609 (on package 601) from being locked between leads 612, 613, and 614 (on package 606). The spaces created by the alternating T-shaped leads allow package 601 and leads 607-610 to move rightward in the figure and thereby not be locked together with package 606 and leads 611-614. This configuration prevents multiple semiconductor packages from becoming entangled during production, testing, or other processes.

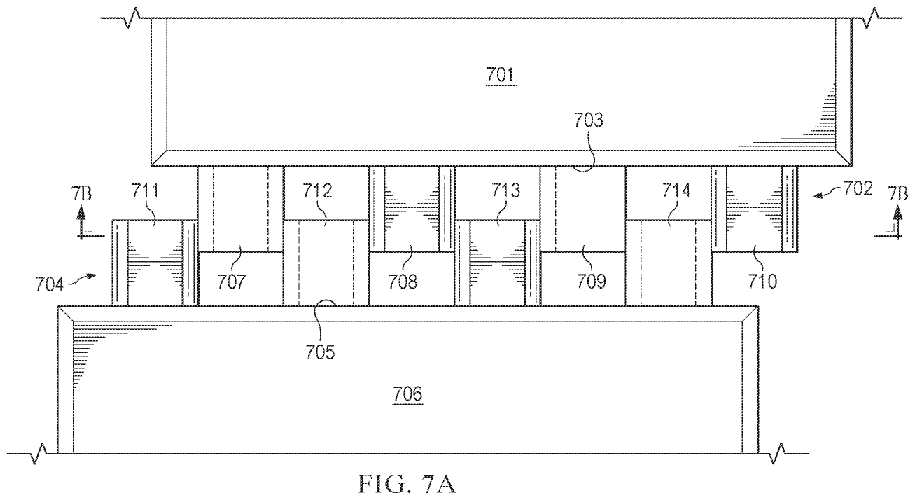

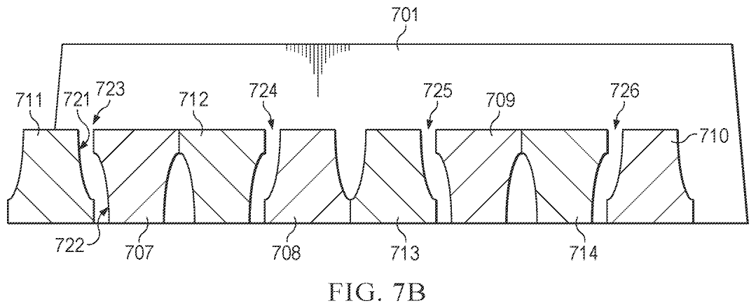

FIG. 7A illustrates adjacent semiconductor packages having a different external lead configuration compared to FIG. 6A. FIG. 7A shows a top-down view of a first semiconductor package 701 having a first set of external leads 702 extending from side 703. External leads 702 are interleaved with a second set of external leads 704 that extend from side 705 of a second semiconductor package 706. The first set of external leads 702 includes upright T-shaped leads 707 and 709 that are interspaced with inverted T-shaped leads 708 and 710. The second set of external leads 704 includes upright T-shaped leads 711 and 713 that are interspaced with inverted T-shaped leads 712 and 714.

The external leads on packages 601 and 602 (FIG. 6A) and package 701 (FIG. 7A) have the same pattern. Looking from left to right, the order of the T-shaped external leads is upright, inverted, upright, inverted. On the other hand, the external leads on package 706 (FIG. 7A) have the pattern inverted, upright, inverted, upright. This difference is highlighted by comparing FIGS. 6B and 7B.

FIG. 7B is a cross-section view through the interleaved sets of external leads 702, 704. The orientation of the external leads on each semiconductor package 701, 706 results in pairs of interleaved leads that have the same orientation (i.e., pair of upright T-shapes or inverted T-shapes). These pairs are offset from the example shown in FIG. 6B due to a different order of the shapes for leads 711-714 compared to leads 611-614. For example, lead 707 from package 701 and adjacent lead 712 from package 706 both have an upright T-shaped configuration. On the other hand, lead 708 from package 701 and adjacent lead 713 from package 706 both have an inverted T-shaped configuration. Because these pairs have the same orientation, external leads 707 and 708 of package 701 bump up against external leads 712 and 713, respectively, on package 706. Therefore, package 701 (and leads 707, 708) cannot move any further rightward in the figure.

The notched region 721 on lead 711 and the notched region 722 on lead 707 create a space 723 between those external leads 711, 707. This space 723 allows external lead 707 to move further leftward in the figure toward lead 711 and away from lead 712. Accordingly, the movement permitted by space 723 prevents lead 707 (on package 701) from being locked between leads 711 and 712 (on package 706). Similarly, notched regions on the other leads create spaces 724-726. Spaces 724-726 prevent leads 708, 709, and 710 (on package 701) from being locked between the leads on package 706. The spaces created by the alternating T-shaped leads allow package 701 and leads 707-710 to move leftward in the figure and thereby not be locked together with package 706 and leads 711-714. This configuration prevents multiple semiconductor packages having different external lead configurations from becoming entangled during production, testing, or other processes.

The lead designs illustrated herein, such as leads having a T-shaped cross-section or a Z-shaped cross-section, are accomplished through normal etching or stamping processes that are used to create a semiconductor leadframe. No additional manufacturing processes are needed to implement such designs into the leadframe. These features may be incorporated into the design itself and allow manufacturers to maintain the same tolerance capability during fabrication as used in standard rectangular cross-section leads. The lead designs illustrated herein maintain the same effective lead width required for surface mount processes.

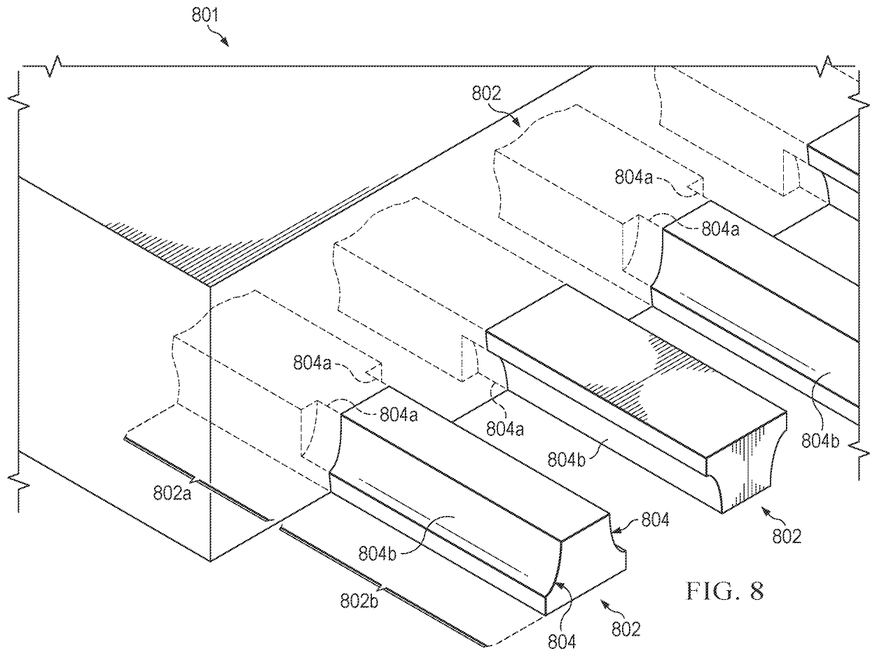

FIG. 8 illustrates a portion of a semiconductor package 801 having several leadframe segments 802. A first portion 802a of each leadframe segment 802 is embedded in a mold compound 803. First portion 802a is typically electrically coupled to a contact on a semiconductor device (not shown) within mold compound 803. A second portion 802b of each leadframe segment 802 is exposed outside mold compound 803 and functions as a connection lead used for exchanging signals with or providing power to the semiconductor device.

The leadframe segments 802 have a T-shaped cross-section and are alternately upright and invented as discussed for various arrangements herein. Each leadframe segment 802 includes a notch region 804 that has been created by etching or stamping the leadframe to define the T-shape cross-section. The notch region 804a continues on at least part of the first portion 802a of each leadframe segment 802. The notch region 804a is embedded within the mold compound and provides a mold lock feature for the leadframe segments 802. The additional surface area and angles created by the notch region 804a allow the mold compound to securely lock onto the leadframes segments 802.

The portions 804b of the notch regions that are exposed outside of mold compound provide additional surface area to improve surface mounting of package 801. The grooves 804b on the exposed 802b portion of the leadframe segments 802 provide additional surface area and features for solder paste to securely lock onto when a package 801 is mounted on a Printed Circuit Board (PCB) or ceramic substrate, such as a Direct Copper Bonded ceramic substrates (DCB).

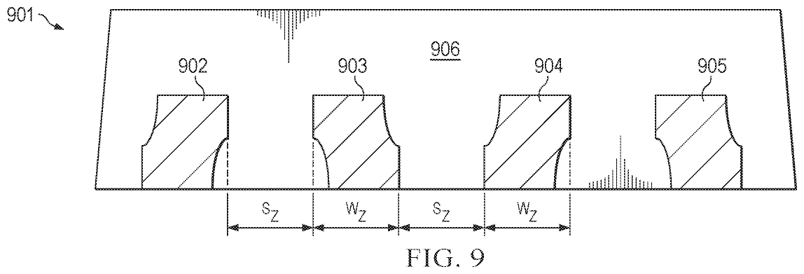

FIG. 9 is a side view of a semiconductor package 901 having a number of external leads 902-905 that are extending from mold compound 906. The external leads 902-905 have a generally Z-shaped cross-section instead of the T-shaped cross-section as shown in FIGS. 3-8. Also, the shape of the external Z-shaped leads 902-905 alternate so that the orientation of each lead is opposite to its neighboring leads. As shown in FIG. 9, leads 902 and 904 have a backward-facing Z-shape cross-section while leads 903 and 905 have a forward-facing, Z-shape cross-section. The external Z-shaped leads 902-905 have a maximum width WZ and are spaced a distance S_{Z} apart so that the external leads 902-905 can be spaced apart by the width of the leads.

Although four external leads are shown on the side of semiconductor package 901, it will be understood that the use of alternating leads with a Z-shaped cross-section may be applied to semiconductor packages having any number of external leads. Furthermore, it will be understood that the use of alternating lead cross-section shapes may be applied to semiconductor packages having different numbers of external leads on two or more sides of the semiconductor packages (e.g., four external leads on one side and six external leads on an opposite side).

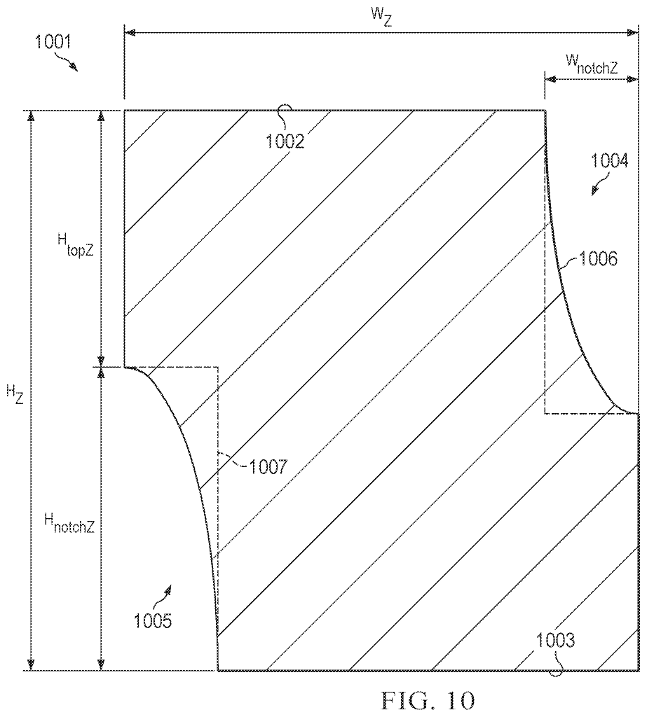

FIG. 10 is a cross-section view of an external lead 1001 according to an alternative configuration. Lead 1001 has a generally Z-shaped cross-section with offset top 1002 and bottom 1003 end. Lead 1001 has an overall width W_{Z} and a height Hz. The external lead 1001 is a portion of a leadframe that has been singulated from a leadframe strip during manufacturing of a semiconductor package. The lead 1001 is a metal material, such as copper, that has been cut, stamped, or etched to create the Z-shaped cross-section of lead 1001.

Material has been removed to create notched regions 1004, 1005 along opposite sides of lead 1001. Depending upon the amount of material removed and the process used to remove the material (e.g., etching, stamping, or cutting), the notched regions 1004, 1005 may have a sloped surface 1006. In another arrangement, removal of material may create notch regions having flatter or squared off surface as shown by dashed line 1007. The notch regions have a width W_{notchZ} and a height H_{notchZ}. In one arrangement, the width of W_{notchZ} is approximately 15% of W_{Z}, and the length of H_{notchZ} is approximately 75% of Hz.

There are two notch regions 1004, 1005 on lead 1001. In some arrangements, the width W_{notchZ} and the height H_{notchZ} of both notches 1004, 1005 are the same. In other arrangements, notch regions 1004 and 1005 may have different heights and/or widths so that on one side notch region 1004 is wider and/or higher than notch region 1005 on the other side of the lead. While lead 1001 is shown in FIG. 10 in a forward-facing Z-shape configuration, it will be understood that a backward-facing Z-shape configuration may be created by removing material from the opposite sides of lead 1001 as shown to create the notched regions. The height of either notch region 1004, 1005 should exceed the largest height H_{topZ} of the top or bottom ends 1002, 1003. This spacing will allow adjacent forward-facing and backward-facing Z-shaped leads 1001 to overlap.

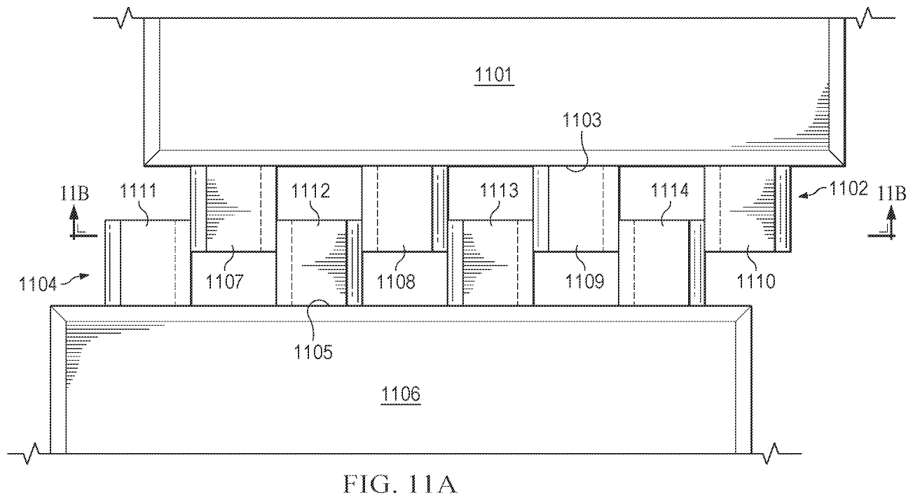

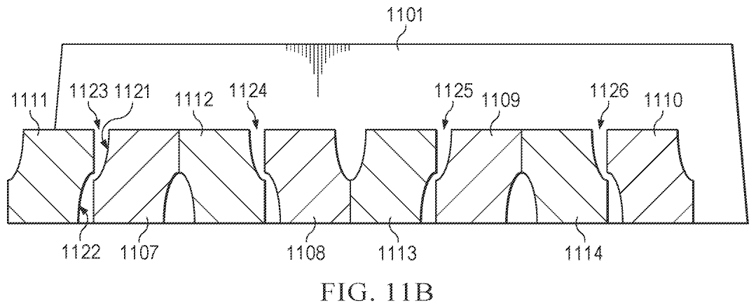

FIG. 11A shows a top-down view of a first semiconductor package 1101 having a first set of external leads 1102 extending from side 1103. External leads 1102 are interleaved with a second set of external leads 1104 that extend from side 1105 of a second semiconductor package 1106. The first set of external leads 1102 includes backward-facing Z-shaped leads 1107 and 1109 that are interspaced with forward-facing Z-shaped leads 1108 and 1110. The second set of external leads 1104 includes backward-facing Z-shaped leads 1111 and 1113 that are interspaced with forward-facing Z-shaped leads 1112 and 1114.

FIG. 11B is a cross-section view through the interleaved sets of external leads 1102, 1104. The orientation of the external leads on each semiconductor packages 1101 and 1106 results in pairs of interleaved leads that have the same orientation (i.e., pairs of forward-facing Z-shapes or pairs of backward-facing Z-shapes). For example, lead 1107 from package 1101 and adjacent lead 1111 from package 1106 both have a backward-facing Z-shaped configuration. On the other hand, lead 1108 from package 1101 and adjacent lead 1112 from package 1106 both have a forward-facing Z-shaped configuration. Because these pairs have the same orientation, external leads 1107 and 1108 of package 1101 bump up against external leads 1112 and 1113, respectively, on package 1106. Therefore, package 1101 (and leads 1107, 1108) cannot move any further rightward in the figure.

The notched region 1121 on lead 1107 and the notched region 1122 on lead 1111 create a space 1123 between those external leads 1107, 1112. This space 1123 allows external lead 1107 to move further leftward in the figure toward lead 1111 and away from lead 1112. Accordingly, the movement permitted by space 1123 prevents lead 1107 (on package 1101) from being locked between leads 1111 and 1112 (on package 1106). Similarly, notched regions on the other leads create spaces 1124-1126. Spaces 1124-1126 prevent leads 1108 and 1109 (on package 1101) from being locked between leads 1112, 1113, and 1114 (on package 1106). The spaces created by the alternating Z-shaped leads allow package 1101 and leads 1107-1110 to move leftward in the figure and thereby not be locked together with package 1106 and leads 1111-1114. This configuration prevents multiple semiconductor packages from becoming entangled during production, testing, or other processes. These feature are incorporated on the package leadframe design itself and will be detectable on a final product. These feature may be observed on an external lead through visual inspection and observed within the package through an X-ray cross section.

Referring again to FIG. 2, each set of external leads 202a, 202b and 204, 204b on the same side of a semiconductor package 201 or 203 are arranged with alternating cross-section shapes. The order of the alternating shapes may be mirrored on each side of the packages 201, 203. For example, from top to bottom leads 202a, 202b and 204, 204b may be ordered as upright, inverted, upright, inverted T-shapes. Alternatively, the order of the alternating shapes may be offset on each side of the packages 201, 203. For example, from top to bottom leads 202a, 204a may be ordered as upright, inverted, upright, inverted T-shapes while leads 202b, 204b are ordered as inverted, upright, inverted, upright T-shapes. In either order (i.e., compare FIG. 6B to FIG. 7B), as long as the external leads' cross-sections alternate, then there will be space available if the external leads become interleaved, which will prevent the packages from being entangled and stuck together.

In one arrangement, a semiconductor package comprises a leadframe segment having a plurality of external leads. The external leads each have a first cross-section shape or a second cross-section shape. A semiconductor die is electrically coupled to the leadframe segment. An encapsulant covers the semiconductor die. The external leads are exposed on at least one side of the semiconductor package through the encapsulant. The external leads are arranged on at least one side to alternate between the first cross-section shape and the second cross-section shape so that the orientation of each external lead is opposite to its neighboring leads. The external leads are spaced apart by the width of the external leads. The first cross-section shape and the second cross-section shape can be created by etching material from the external leads or by stamping a leadframe sheet to form the external leads. At least a portion of each external lead can be covered by the encapsulant, where the covered portions of the external leads have either the first cross-section shape or the second cross-section shape that provides a surface to lock the encapsulant to the leads.

The second cross-section shape may be a mirror image of the first cross-section shape. The first cross-section shape may be an upright T-shape while the second cross-section shape is an inverted T-shape, where the lead width is a width of a horizontal bar on the T-shape cross-section. The first cross-section shape may be a forward-facing Z-shape while the second cross-section shape is a backward-facing Z-shape, where the lead width is a width from an outside edge of an upper horizontal bar to an outside edge of a lower horizontal bar on the Z-shape cross-section.

In another arrangement, a semiconductor device comprises an IC die mounted on a leadframe. A mold compound covers the IC die and at least a portion of the leadframe. A first group of leadframe leads are exposed from a first side of the mold compound. Each of the first group of lead portions have a cross-section shape. The cross-section shape of adjacent leads on the first side alternate between a first shape or a second shape so that the orientation of each lead is opposite to its neighboring leads. The leads have the same lead width, and the leads are spaced apart by the lead width. A second group of leadframe leads are exposed from a second side of the mold compound. The cross-section shape of adjacent leads on the second side alternate between the first shape or the second shape. The cross-section shape is defined by notches in the leads. The notches are configured to permit unrestrained movement when a second group of leads on another semiconductor device are interleaved between the first group of leads. The first shape is an upright T-shape or a forward-facing Z-shape, and the second cross-section shape is an inverted T-shape or a backward-facing Z-shape.

In an alternative arrangement, a leadframe segment for a semiconductor package comprises a first set of external leads each having a first cross-section shape and a second set of external leads each having a second cross-section shape. The second set of external leads are interleaved between the first set of external leads so that the orientation of each lead is opposite to its neighboring leads. Each of the external leads in the first set and the second set have a same lead width, and adjacent external leads are spaced apart by the lead width. The first cross-section shape may be an upright T-shape formed by etching material from opposite bottom corners of the first set of external leads, and the second cross-section shape is an inverted T-shape formed by etching material from opposite top corners of the second set of external leads. The first cross-section shape may also be a forward-facing Z-shape formed by etching material from a first pair of diagonally opposed top and bottom corners on the first set of external leads, and the second cross-section shape is a backward-facing Z-shape formed by etching material from a second pair of diagonally opposed top and bottom corners on the second set of external leads. The first cross-section shape and the second cross-section shape are configured to permit unrestrained movement when external leads of two semiconductor packages are interleaved.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. A semiconductor package, comprising:
a leadframe segment having a plurality of external leads, the external leads each having a first cross-section shape or a second cross-section shape;
a semiconductor die electrically coupled to the leadframe segment; and
an encapsulant covering the semiconductor die and exposing the external leads on at least one side of the semiconductor package, the external leads arranged on the at least one side to alternate between the first cross-section shape and the second cross-section shape so that the orientation of each external lead is opposite to its neighboring leads.

2. The semiconductor package of claim 1, wherein second cross-section shape is a mirror image of the first cross-section shape.

3. The semiconductor package of claim 1, wherein the first cross-section shape is an upright T-shape and the second cross-section shape is an inverted T-shape.

4. The semiconductor package of claim 1, wherein the first cross-section shape is a forward-facing Z-shape and the second cross-section shape is a backward-facing Z-shape.

5. The semiconductor package of claim 1, wherein the external leads have a lead width and the external leads are spaced apart by the lead width.

6. The semiconductor package of claim 5, wherein the lead width is a width of a horizontal bar on a lead with a T-shape cross-section.

7. The semiconductor package of claim 5, wherein the lead width is a width from an outside edge of an upper horizontal bar to an outside edge of a lower horizontal bar on a lead with a Z-shape cross-section.

8. The semiconductor package of claim 1, wherein the first cross-section shape and the second cross-section shape are created by etching material from the external leads.

9. The semiconductor package of claim 1, wherein the first cross-section shape and the second cross-section shape are created by stamping a leadframe sheet to form the external leads.

10. The semiconductor package of claim 1, wherein at least a portion of each external lead is covered by the encapsulant, and wherein the covered portions of the external leads have either the first cross-section shape or the second cross-section shape.

11. A semiconductor device, comprising:
an integrated circuit (IC) die mounted on a leadframe;
a mold compound covering the IC die and at least a portion of the leadframe; and
a first group of leadframe leads exposed from a first side of the mold compound, each of the first group of lead portions having a cross-section shape, wherein the cross-section shape of adjacent leads on the first side alternate between a first shape or a second shape so that the orientation of each lead is opposite to its neighboring leads.

12. The semiconductor device of claim 11, wherein the leads have a same lead width and the leads are spaced apart by the lead width.

13. The semiconductor device of claim 11, further comprising:
a second group of leadframe leads exposed from a second side of the mold compound, each of the second group of lead portions having a cross-section shape, wherein the cross-section shape of adjacent leads on the second side alternate between the first shape or the second shape.

14. The semiconductor device of claim 11, wherein the cross-section shape is defined by notches in the leads, and wherein the notches are configured to permit unrestrained movement when a second group of leads on another semiconductor device are interleaved between the first group of leads.

15. The semiconductor device of claim 11, wherein the first shape is an upright T-shape or a forward-facing Z-shape and the second cross-section shape is an inverted T-shape or a backward-facing Z-shape.

16. A leadframe segment for a semiconductor package, comprising:
a first set of external leads each having a first cross-section shape; and
a second set of external leads each having a second cross-section shape, the second set of external leads interleaved between the first set of external leads so that the orientation of each lead is opposite to its neighboring leads.

17. The leadframe segment of claim 16, wherein each of the external leads in the first set and the second set have a same lead width, and wherein adjacent external leads are spaced apart by the lead width.

18. The leadframe segment of claim 16, wherein the first cross-section shape is an upright T-shape formed by etching material from opposite bottom corners of the first set of external leads, and wherein the second cross-section shape is an inverted T-shape formed by etching material from opposite top corners of the second set of external leads.

19. The leadframe segment of claim 16, wherein the first cross-section shape is a forward-facing Z-shape formed by etching material from a first pair of diagonally opposed top and bottom corners on the first set of external leads, and wherein the second cross-section shape is a backward-facing Z-shape formed by etching material from a second pair of diagonally opposed top and bottom corners on the second set of external leads.

20. The leadframe segment of claim 16, wherein the first cross-section shape and the second cross-section shape are configured to permit unrestrained movement when external leads of two semiconductor packages are interleaved.
